(19) United States
(12) Patent Application Publication
(10) Pub. No.: US 2011/0111350 A1
(43) Pub. Date: May 12, 2011

(54) Conjugated Polymers

(76) Inventors: Dhana Lakshmi, Cranfield Bedfordshire (GB); Michael James Whitcombe, Norfolk (GB); Iva Chianella, Bedfordshire (GB); Sergey Anatoliyovich Piletsky, Bedfordshire (GB)

(21) Appl. No.: 12/934,811

(22) PCT Filed: Mar. 26, 2009
(86) PCT No.: PCT/GB2009/000795

§ 371 Date: Dec. 13, 2010

(30) Foreign Application Priority Data
Mar. 26, 2008 (GB) 0805452.0

(51) Int. Cl. G03F 7/20; C08F 120/60; C08F 220/60; C09D 133/26; C08F 2/46; C25B 3/00

(52) U.S. Cl. 430/325; 526/305; 524/555; 522/113; 525/328.4; 205/414

(57) ABSTRACT

A monomer M-S has a first polymerisable moiety (M) capable of forming a conjugated polymer, and a second polymerisable moiety (S) with a double bond susceptible to addition polymerisation. Polymerisation of the M-moieties is caused, generally by electropolymerisation or chemical oxidation. Polymerisation of the S-moieties is also caused, generally by a radical mechanism, before, after or simultaneously with the M-polymerisation. Suitable monomers include N-(methacrylamidoethyl)-aniline, N-(acrylamidoethyl)-aniline, N-(methacryloyloxyethyl)-aniline and N-(acryloyloxyethyl)-aniline.

### TECHNICAL FIELD

The invention relates to polymers that include conjugated chains, to methods for preparing them, and to monomers suitable for use in preparing them.

### BACKGROUND

Electrically conducting conjugated polymers (CPs) date back to the discovery of polypyrrole (PPy) in the 1960s, but little was understood about the polymer at this time and the discovery was essentially lost [1]. It was only in 1977, when MacDiarmid, Shirakawa, and Heeger reported a 10 million-fold increase in the conductivity of polyacetylene doped with iodine that the first inherently conductive polymer was recognized [2]. Although polyacetylene, a non-cyclic polyene, is still one of the most studied polymers in this field, it has significant limitations, such as difficulty with processing and high instability in air. Consequently, the development of aromatic CPs for different applications has received much attention. These include polypyrrole (PPy), polythiophene (PT), polyaniline (PANI) and poly (3,4-ethylenedioxythiophene) (PEDOT). Developed in the 1980s, these materials have since emerged as CPs that exhibit excellent stability, conductivity, and ease of synthesis [3]. They have found widespread application in areas such as microelectronics, including batteries, antistatic materials, corrosion prevention, photovoltaic devices, light emitting diodes, and electrochromic displays and in sensor technology [4]. The two common properties desired for sensor applications of CPs are mediator properties and pH- and redox-dependence of polymer conductivity. Several research groups have focused on biological and physical modification of CPs. Still there are several limitations such as short-term redox stability, hydrophobicity, poor solubility, biocompatibility, delamination of CP films, non-biodegradability, low porosity [5] and lack of chemical specificity which should be overcome. The current practice to meet these demands, address these issues and to assure highly specific conducting system is still lacking.

It is often desirable to chemically modify the structure of the polymers to suit the intended application, e.g. by use of modified monomer structures. [U.S. Pat. No. 7,317,047, U.S. Pat. No. 7,318,995, U.S. Pat. No. 7,195,834, WO 2008 019744, CN 101016355]. One example is the N-substitution of a pyrrole monomer with a carboxyethyl group to form polymers for cell adhesion [6]. However the conductivity of the resultant polymers, formed as either electrically polymerised films or chemically polymerised powders, was approximately four orders of magnitude lower than unsubstituted PPy prepared in the same manner [6]. A method therefore to functionalise CPs without substantial loss of conductivity, or even resulting in an increase in conductivity, is still desirable.

For microelectronics purposes, the ability to deposit conductive material by photolithography is critically important [U.S. Pat. No. 7,318,995]. The current invention also provides ways for adapting conjugated polymers to this process. In particular the method of the current invention does not require additional photoresist coating, imaging and development stages required by other methods [7, 8] or other complex processing steps, e.g. microcontact printing [9, 10]. In some embodiments, conducting polymer precursors can themselves act as the photoimaging material. Moreover all the processing steps can be performable using aqueous reagents with reduced environmental impact.

The stability of the created conductive polymers is also very important for sensor and microelectronics applications. To achieve it, chemical and physical cross-linking has been applied [U.S. Pat. No. 7,335,795, U.S. Pat. No. 7,321,012, U.S. Pat. No. 6383415]. The current invention provides the ability to create interpenetrated polymeric networks consisting of conjugated and additive polymers, with high conductivity and mechanical, chemical and thermoresistance.

### REFERENCES

1. Street G. B., Polypyrrole: from powders to plastics. In: Skotheim T. A., Ed. Handbook of conducting polymers, Vol. I., Marcel Dekker: New York; 1986. p. 265-91.
2. Shirakawa H., Louis E. J., MacDiarmid A. G., et al., J. Chem. Soc. Chem. Commun., 1977,78-80.
3. Feast W. J., Synthesis of conducting polymers. In: Skotheim T. A., Ed. Handbook of conducting polymers, Vol. I., Marcel Dekker: New York; 1986. 1-43.
4. Gurunathan K., Murugan A. V., Marimuthu R., et al., Mater. Chem. Phys., 1999, 61, 173-9.
5. Guimard N. K., Gomez N., Schmidt C. E., Prog. Polym. Sci., 2007, 32, 876-921.
6. Lee J. W., Serna F., Nickels J., Schmidt C. E., Biomacromolecules, 2006, 7, 1692-1695.
7. Makela. T., Pienimma S., Jussila S., Isotalo H., Synth. Met., 1999,-101, 705-706.
8. Balocco C., Majewski L. A., Song A. M., Org. Electron., 2006, 7, 500-507.
9. Lee K. S., Blanchet G. B., Gao F., Loo Y -L., Appl Phys Lett., 2005, 86, 074102.
10. Collard D. M., Sayre C. N., Synth Metals. 1997, 84, 329-332.

### PATENT REFERENCES

| Patent | Issued | Title |
|---|---|---|
| U.S. Pat. No. 7,335,795 | 2008-02-26 | Cross-linked amine polymers |
| U.S. Pat. No. 7,317,047 | 2008-01-08 | Electrically conducting organic |
| | | polymer/nanoparticle composites |
| | | and methods for use thereof |
| U.S. Pat. No. 7,321,012 | 2008-01-22 | Method of cross-linking |
| | | intrinsically conductive |
| | | polymers or intrinsically |
| | | conductive polymer precursors |
| | | and the articles obtained |
| | | therefrom |
| U.S. Pat. No. 7,318,995 | 2008-01-15 | Method of making a negative- |
| | | working lithographic printing |
| | | plate |
| U.S. Pat. No. 7,095,474 | 2006-08-22 | Patterns of electrically |
| | | conducting polymers and their |
| | | application as electrodes or |
| | | electrical contacts |
| U.S. Pat. No. 7,195,834 | 2007-03-27 | Metallized conducting polymer- |
| | | grafted carbon material and |
| | | method for making |
| W02008019744 | 2008-02-21 | Conjugated polymers, process |
| | | for their preparation and their |
| | | use |
| CN101016355 | 2007-08-15 | Functionalized polymers |
| U.S. Pat. No. 6,383,415 | 2002-05-07 | Methods of fabrication of cross- |
| | | linked electrically conductive |
| | | polymers and precursors thereof |
| U.S. Pat. No. 6,193,909 | 2001-02-27 | Cross-linked electrically |
| | | conductive polymers, precursors |
| | | thereof |
| U.S. Pat. No. 4,959,180 | 1990-09-25 | Colloidal polyaniline |

### DISCLOSURE OF INVENTION

In a first aspect the invention provides a method of preparing a polymer comprising:

(a) providing a monomer of the form M-S where M is a moiety capable of polymerisation to form a conjugated polymer chain, and S is a moiety including a double bond whereby it is capable of addition polymerisation;

(b) causing polymerisation of the M-moieties, optionally together with a comonomer, to form a conjugated polymer chain;

(c) causing polymerisation of the S-moieties, optionally together with a comonomer;

wherein steps (b) and (c) are carried out in either order or simultaneously.

In a second aspect the invention provides a polymer derivable from monomers comprising monomers of the form M-S where M is a moiety capable of polymerisation to form a conjugated polymer chain, and S is a moiety including a double bond whereby it is capable of addition polymerisation; said polymer having conjugated polymer chains as derived from polymerisation of said M moieties, optionally together with a comonomer; said conjugated polymer chains being cross-linked by linkages as derived from polymerisation of said S moieties, optionally together with a comonomer.

In a third aspect the invention provides monomers for use in the first two aspects, in particular N-(methacrylamidoethyl)-aniline, N-(acrylamidoethyl)-aniline, N-(methacryloyloxyethyl)-aniline and N-(acryloyloxyethyl)-aniline.

This invention can employ monomers such as aniline, acetylene, pyrrole or thiophene (M) bearing a substituent (S) containing at least one double bond, such that the material is capable of being polymerized in two distinct fashions, namely (i) through the M moiety, (for example by chemical oxidation or by electropolymerization) to form conjugated polymer chains; and (ii) through addition polymerization of the double bond (for example by free radical polymerization) to form an addition polymer. The invention also relates to polymers made from these monomers, in which some or all of the two types of polymerizable groups (e.g. aniline and double bond) have been converted to polymers or copolymers. The two polymerization reactions may be carried out in different orders: (i) formation of the conjugated polymer by polymerization or copolymerization of the M moiety, followed by polymerization or copolymerization of the double bond in a one- or two-step process resulting in the grafting of addition polymers to the polyaniline material and/or in cross-linking of the polyaniline material; (ii) reversed order of polymerization when the double bond is polymerized or copolymerized to form a linear, branched or cross-linked addition polymer bearing M side-chains connected to the addition polymer backbone, followed by polymerization of the M moieties to form a conjugated polymer network; (iii) the simultaneous polymerization of the M and double bond moieties using an initiator or mixture of initiators that is both a chemical oxidant for the M moiety and also can act as an initiator for polymerization of double bonds.

The monomers used in the present invention are generally molecules with two polymerization centres with orthogonal reactivities and, as such, are versatile materials with many different potential applications. Applications of the polymers include, but are not limited to: conductive layers in electrochemical sensors, fuel cells and batteries, and/or radiation shielding and anti-static layers; corrosion resistant and biocompatible coatings; lithographic patterning of conductive polymer tracks in electrical circuits and microelectronics; microwave protective shielding and filtering coatings for military and domestic applications (Stealth and Radar technologies); conductive fabrics for personal electronics, anti-static clothing, radiation shielding and stealth clothing and protection of static-sensitive electronic devices; coatings for use in electrostatic dissipation in commercial and domestic applications; electroluminescent display devices, i.e. for organic LED's and flat-panel displays; use as photochromic materials for Smart Window technology; use as photorecording and photosensitive materials; and “invisible inks” for novelty and security applications.

FIG. 1 shows how a monomer of the type used in this invention can be polymerized in two orthogonal manners, through the “M” moiety to form a conjugated polymer or copolymer or through the double bond to form an addition polymer. The order in which the polymerization reactions are carried out will determine the properties of the material and determine which applications it is suited to.

FIG. 2 shows two-stage cross-linking and/or grafting to an electropolymerised film using a photoiniferter.

The monomers used in the present invention are preferably those in which the substituent S is attached to the M-moiety in a position not interfering with the polymerization of the M moiety. The chemical entity containing the double bond may be connected to the M moiety by a spacer group of 2 to 6 atoms in length. The spacer group can consist of alkyl, alkoxy, ether, ester, amide, ketone or other similar spacer group known to practitioners in the art. It is preferably an alkyl group, the preferred embodiment being an alkyl group of 2 carbon atoms in length, preferably an ethylene spacer. It is also preferred that the M group is an (optionally substituted) aniline group, preferably unsubstituted at the 4 position. Preferably the substituent S is attached to the aniline group at the nitrogen atom. The double bond entity can be any double bond containing unit capable of polymerization by free radical means. Examples include vinyl ketone, allyl group, vinyl aromatic group, vinyl ether, vinyl carbonate, vinyl carbamate, acrylate ester, acrylamide, methacrylate ester, methacrylamide, chloroacrylate ester, chloroacrylamide, itaconic acid ester, itaconamide, allyl ester, allyl ether, vinyl benzyl ether, vinyl benzyl ester, vinyl benzoate ester, vinylphenol ester, and vinylphenol ether. In the preferred embodiment the polymerizable group is an acrylate or methacrylate ester or an acrylamide or methacrylamide group. Particularly preferred monomers are: N-(methacrylamidoethyl)-aniline, N-(acrylamidoethyl)-aniline, N-(methacryloyloxyethyl)-aniline and N-(acryloyloxyethyl)aniline (see FIG. 3).

In a first class of embodiments of the method of the invention, the M moiety is polymerized or copolymerized first, followed by polymerization or copolymerization of the double bond in a second process. The M moiety can be polymerized or copolymerized with other monomers with the same polymerizable entity, either in the unsubstituted form or bearing substituents, provided those substituents do not interfere with the process of polymerization. The polymerization or copolymerization process can be carried out electrochemically, at the surface of an electrode, using electrode materials, pH buffers and/or electrolytes, reference electrodes and electronic control apparatus known to those skilled in the art, for example a gold working electrode, platinum counter electrode and silver/silver chloride reference electrode in an acidified aqueous solution of the monomer or monomer mixture, suitably controlled using an Autolab electrochemistry set-up and control software running on a PC. Alternatively the M moiety can be polymerized or copolymerized from solution using an oxidizing agent which is capable of polymerizing or copolymerizing the M moieties without affecting or substantially affecting the double bond entities. This step can be carried out in an aqueous solution with or without pH control, or in organic solution. The products of polymerization may be soluble or insoluble, depending on the solvent and monomer structure and polymer composition. Alternatively the polymerization of the M moieties can be carried out in a suspension or emulsion polymerization or inverse suspension or inverse emulsion polymerization process to give rise to particles, soluble or insoluble polymer or colloidal dispersions of polymer particles, the particle dimensions being desirably between 10 nm and 100 μm, according to the methods known to those skilled in the art [U.S. Pat. No. 4,959,180].

Having prepared the polymer or copolymer incorporating the M units, some or all of the double bond units can then be polymerized or copolymerized to form polymers of the invention. This second polymerization step may involve mixing the polymer formed in the first polymerization with initiators and optionally other monomer(s), e.g. comprising crosslinking monomers, and heating or irradiating to initiate the second polymerization; coating the polymer as a solution or as a dry particulate material or colloidal suspension or as a slurry, with an initiator and optionally additional monomer(s), e.g. comprising cross-linkers, onto a surface to be coated with the materials of the invention and initiating the second polymerization with heat or by irradiation; immersing an electropolymerized film into a solution containing an initiator and optionally additional monomer(s), e.g. comprising cross linkers, and initiating the second polymerization by heating or irradiating; by a two-step process involving immersing an electropolymerized film into a solution of an initiator such as a photochemically-activated or thermally activated iniferter, and irradiating or heating to cause attachment of the iniferter to the exposed double bonds on the surface of the electropolymerized film, either with or without cross-linking of the film, followed by immersion in a fresh solution containing additional monomer(s), e.g. comprising cross-linkers, and grafting to the electropolymerized film by initiating the second polymerization between the added monomers and the double bonds of the electropolymerized film with either heating or by irradiation. Such grafted material can be prepared in the presence of a molecular or macromolecular template, or other such template known to those skilled in the art, to prepare a grafted film of molecularly imprinted polymer (MIP). After removal of the template, this contains cavities complementary in size, shape and functionality to the template. It may be used for recognition and/or catalysis. When the cavities are formed in the vicinity of the conjugated polymer formed in the first polymerization, such MIP-grafted electropolymerized films may be useful as molecularly imprinted sensors. The above examples are illustrative only and practitioners in the art will be fully aware of other possibilities not mentioned which are contained within the compass of the invention.

In a second class of embodiments of the invention, the first polymerization step is the polymerization or copolymerization of the double bond moiety, followed by a second polymerization step in which some or all of the M moieties of the first formed polymer are polymerized or copolymerized to form polymers of the invention. The first polymerization step can be carried out in the molten state or in solution, including organic or aqueous solution, with or without pH control; in an emulsion or suspension polymerization; in an inverse emulsion or inverse suspension polymerization; or in any other polymerization system known to those skilled in the art. It may occur in the presence of an initiator, or an initiator and additional monomer(s), optionally including one or more cross-linkers. It may be initiated by means of heating or irradiation to form a monolith, insoluble or soluble polymer, fibre, particle or moulded item. In the case of particles, the particles can be in the size range from 10 nm to 100 μm in diameter.

The first polymerization can be initiated in a film or layer of the monomer or solution of the monomer, containing an initiator or an initiator and additional monomer(s), optionally containing at least one cross-linker. The film or layer may be prepared by spin-coating, dip-coating, spray-coating or by application with a brush or by screen-printing or any other method known to those skilled in the art. Polymerisation may be initiated by irradiation through a mask or by projection or with an interference pattern or hologram to result in lithographic patterning or spatial modulation in the formation of the first-formed polymer, such that development with a solvent (which may be aqueous, partly aqueous or organic, with or without surface active agents) after exposure, results in selective dissolution of the monomers in preference to the polymer. Thus lithographic patterns or spatial modulations are preserved as polymer features on the surface of the coated article.

In another type of embodiment, the monomer and initiator or an initiator and additional monomers, optionally including one or more cross-linkers, as a neat mixture or as a solution, is coated on the surface of an article by spin-coating, dip-coating, spray-coating or applied with a brush or screen-printing or any other method known to those skilled in the art, to form a continuous film over one or more surfaces or over the entirety of the article. Heating or irradiation then initiates polymerization of the double bond moieties to form a surface coating or film of the first formed polymer on the article.

In another type of embodiment, the monomer and an initiator or an initiator and additional monomers, optionally including one or more cross-linkers, as a neat mixture or as a solution, is selectively applied to an article by contact printing, microcontact printing, brushing, printing, including screen-printing, inkjet printing, direct transfer, by brush or pen or any other means known to those skilled in the art, before initiating polymerization by heating or by irradiation such that the coating applied to the object forms a spatially-modulated pattern, such as tracks, grids, alphanumeric characters, barcodes or other symbols or other features or connections used in the final application.

In another type of embodiment, the first formed polymer, in its molten state or as a solution or as a suspension of particles or a slurry or as a colloidal dispersion, is applied to an article as a surface coating by spin-coating, dip-coating, spray-coating or with a brush or screen printing, or any other method known to those skilled in the art, to form a surface coating after solvent evaporation or cooling to harden the layer. The melt, solution, suspension or slurry can optionally contain one or more additional monomers bearing the M moiety, either substituted or unsubstituted, provided that the substituents do not interfere with the polymerization behaviour of the M moieties. The solution, suspension, slurry or colloidal dispersion optionally contains one or more additional monomers bearing the M moiety, either substituted or unsubstituted, provided that the substituents do not interfere with the polymerization behaviour of the M moieties. It can be applied to one or more surfaces of an article by contact printing, microcontact printing, brushing, printing, including screen-printing, inkjet printing, direct transfer, by brush or pen or any other means known to those skilled in the art, to form spatially-modulated polymer features such as tracks, grids, alphanumeric characters, barcodes or other symbols or other features or connections used in the final application. The solution, suspension, slurry or colloidal dispersion, optionally containing one or more additional monomers bearing the M moiety, either substituted or unsubstituted, provided that the substituents do not interfere with the polymerization behaviour of the M moieties, may be coated onto fibres or onto woven fabric by any of the methods mentioned above. Alternatively the polymer or copolymer prepared in the first polymerization can be spun into fibres, either by melt spinning or extrusion or from solution, optionally in the presence of other polymers, for example acrylic polymers, to form fibres. These fibres can then be used to form mats, felts or fabric or entwined with themselves or with other fibres, either natural or synthetic, to form yarns and threads. These can be knitted, woven, felted, knotted, braided or entwined to form fabrics, twines, ropes, nets, meshes, sheets or articles of clothing.

Having prepared an article comprising a polymer formed in the first polymerization, as detailed above, the formation of the conjugated polymer can be initiated by immersion of the article in a solution capable of initiating the formation of the conjugated polymer in some or all of the M moieties, or by application of said solution, e.g. by spraying or by brushing, to initiate formation of the conjugated polymer chains. Items such as fibres, yarn, threads or ropes can be woven, felted, braided, knitted, or entwined to form mats, felts, fabrics, nets, meshes, sheets or articles of clothing after carrying out the second polymerization, as described above.

Polymers or copolymers formed in the first polymerization as solutions or colloidal dispersions, can be polymerized at an electrode or copolymerized at an electrode in an electrolyte, either alone or in the presence of one or more additional monomers bearing the M moiety, either substituted or unsubstituted, provided that the substituents do not interfere with the polymerization behaviour of the M moieties, by electrochemical polymerization.

In a third class of embodiment, the polymerization or copolymerization of the double bond entity is performed more or less simultaneously, depending on the reactivities and kinetic parameters of the different polymerization reactions, with the polymerization or copolymerization of the M moieties. Use may be made of an initiator that is capable of initiating the polymerization of both types of entity by two independent mechanisms. For example, polymerization of aniline can be performed by chemical oxidation with persulphates, such as ammonium or potassium persulphate in water. The same initiators also can be used to initiate polymerization of (meth)acrylamide monomers in water. In a further aspect of this embodiment, an aqueous solution, with or without pH control, with or without added salt, of M-S monomers is treated with an initiator at the chosen temperature (between the freezing point and boiling point of the solution at the pressure within the reaction vessel). Said solution can optionally contain one or more additional double bond-containing monomers, one or more of which can be cross-linkers. Said solution can optionally also contain one or more additional monomers bearing the M moiety, either substituted or unsubstituted, provided that the substituents do not interfere with the polymerization behaviour of the M moieties. In a further aspect of this embodiment, the mixture of monomers as described above, can be dispersed in an emulsion, or suspension or inverse emulsion or inverse suspension before treatment with an initiator. The products of this embodiment will be insoluble powders, monoliths or particles or colloidal dispersions of particles or films depending on the method used to form the polymer, such methods being known to those skilled in the art. In a further aspect of this embodiment, the polymerization or copolymerization process, either in solution or in a dispersed phase, such as an emulsion or suspension, can be performed in the presence of a molecular or macromolecular template to form a molecularly imprinted polymer (MIP).

The polymers produced by the various processes of the present invention have numerous applications, e.g. as materials, articles, coatings, or fabrics. The polymers can be prepared in insulating or conducting forms, depending on polymerization conditions. Depending on the material properties and application(s) required, the most important areas of the material utilization are (but not limited to):
1. Electroconductive coatings/connections for microelectronics;
2. Flexible circuitry for electronics and personal electronics applications;
3. Materials for screen-printing;
4. Electromagnetic protective shielding materials and coatings, including fabrics and fabric coatings for dissipation of electrostatic charge;
5. Microwave protective shielding and filtering coatings for military and domestic applications (Stealth and Radar technologies, microwave oven windows);
6. Electroluminescent display devices, i.e. for Organic LED's;
7. Use as photochromic materials for Smart Window technology;
8. Novel sensing materials in sensors and arrays. e.g. gas sensors and optical devices;
9. Use in solid state batteries as an environmentally friendly energy source;
10. Use as photorecording and photosensitive materials;
11. For security marking, machine-readable symbols and barcodes;
12. For concealed writing (invisible ink) for security marking and novelty applications;
13. In chemical sensing and separation technologies.

### BRIEF DESCRIPTION OF DRAWINGS

FIG. 1 is a schematic representation of a polymerisation process of the invention.

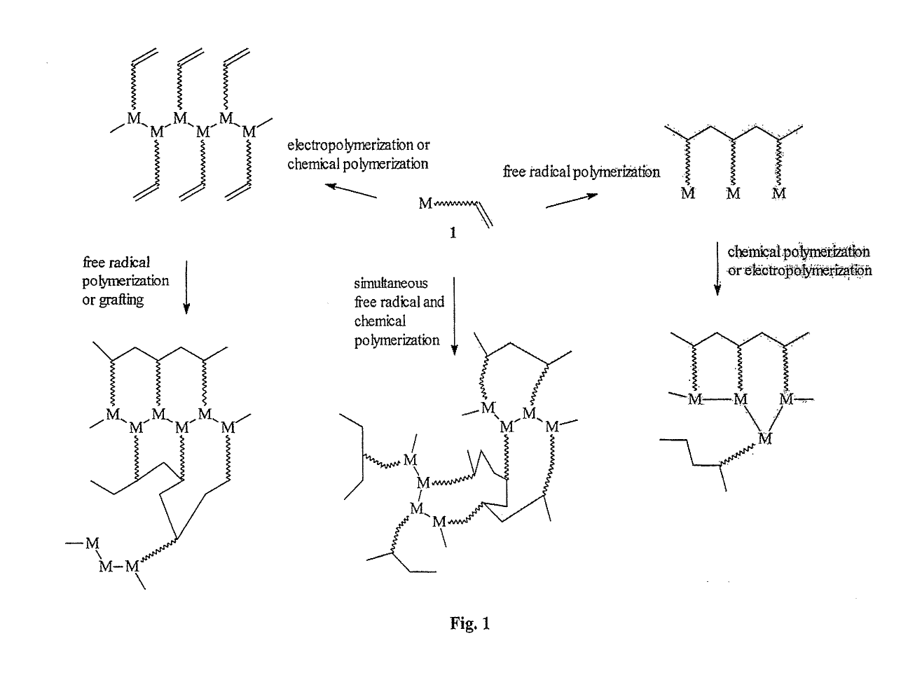

FIG. 2 is a schematic representation of two-stage cross-linking and/or grafting to an electropolymerised film using a photoiniferter.

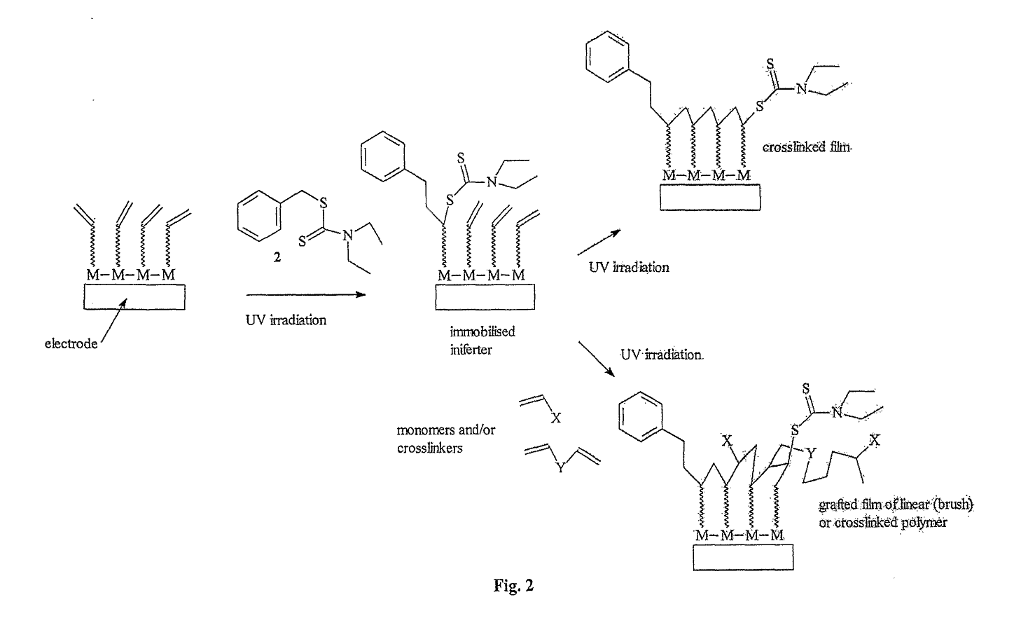

FIG. 3 shows the structures of four preferred monomers.

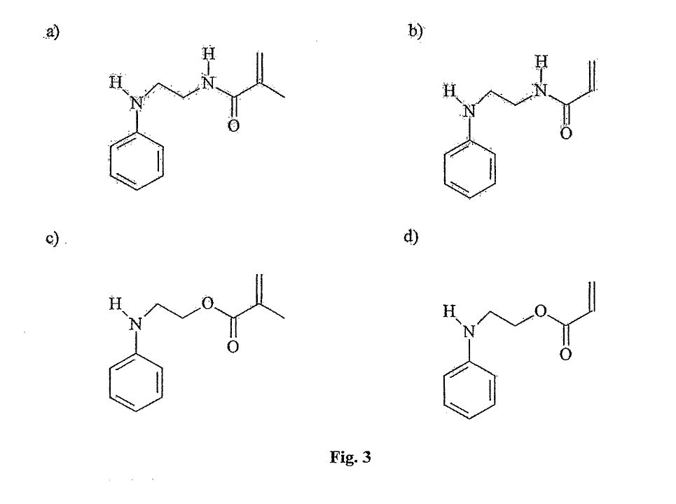

### MODES FOR CARRYING OUT THE INVENTION

### EXAMPLE 1

### Preparation of N-(methacrylamidoethyl)-aniline (NMAEA).

N-phenylethylenediamine (1.0 g, 0.96 ml, 7.3 mmol) was dissolved in methanol (20 ml) which was cooled in ice before the addition of methacrylic anhydride (1.1 g, 1.06 ml, 7.1 mmol). The stirred mixture was held at 0° C. for 3 h before warming to room temperature. The solvent was removed using a rotary evaporator and the residue dispersed in diethyl ether (25 ml). The ether phase was washed with 0.1M NaOH, (4×25 ml) followed by water (1×25 ml) water, dried over anhydrous magnesium sulphate and evaporated to give a brown oil which formed colourless crystals on standing in a refrigerator. The yield was 99%, ¹H nmr, 1.9 (s, 3H, —CH₃), 3.3 (d, 2H, —CH₂), 3.7 (d, 2H, —CH₂), 5.3 (s, 1H, ═CH₂), 5.7 (s, 1H, ═CH₂), 6.6 (d, 2H, ortho-H), 6.7 (t, 1H, para-H), 7.2 (m, 2H, meta-H), ¹³C nmr, 18.6, 39.3, 43.9, 112.7, 117.7, 119.9, 129.3, 139.7 147.9, 169.0, IR (KBr disc) 3345, 3000, 2920, 1655, 1603, 1514, 1322, 750, 694 cm⁻¹.

### EXAMPLE 2

### Preparation of N-(acryloyloxyethyl)-aniline

N-(2-hydroxyethyl)aniline (5 g, 36.4 mmol) was dissolved in ethanol-free chloroform (100 mL) with hydroquinone (2 g), p-toluenesulphonic acid (1 g) and acrylic acid (20 ml, (large excess)). The flask was fitted with a reverse Dean-Stark apparatus, reflux condenser and calcium chloride guard tube. The flask was heated to boiling and the equilibrium was driven by the removal of water separating in the side arm of the Dean-Stark trap. When no further water was seen to be separating from the chloroform distilling into the trap, the mixture was allowed to cool to room temperature. The chloroform layer was transferred to a separating funnel and washed with water (2×25 ml), 0.1 M NaOH (4×25 ml) and water (2×25 ml). The organic layer was dried (MgSO₄), filtered and evaporated to yield the product as an oil.

### EXAMPLE 3

### Free Radical Polymerization of the Double Bond of NMAEA, Followed by Formation of Conjugated Polymer by Chemical Oxidation

NMAEA and mixtures of NMAEA with ethylene glycol dimethacrylate (EGDMA) were polymerized in DMF by thermal free radical polymerization, using the initiator 1,1′-azo-bis-(cyclohexane-1-carbonitrile), according to Table 1. Monomer(s) (200 mg) and initiator (2 mg, 1%) were dissolved in DMF (400 mg). The mixtures were purged with a stream of argon for 5 min before being sealed under an argon atmosphere and transferred to an oil bath held at 80° C. for 16 h. The resultant material was precipitated into water (P0) or washed with methanol (cross-linked polymers). Dried polymers were ground in a mortar and washed with further methanol (5×5 ml) and dried in an oven.

TABLE 1
Composition of free radical polymers and
copolymers of MAEA

| Polymer | NMAEA(mg) | EGDMA(mg) |
|---|---|---|
| P0 | 200 | 0 |
| P5 | 190 | 10 |
| P10 | 180 | 20 |
| P25 | 150 | 50 |
| P50 | 100 | 100 |

Polymer (P0, P5, P10, P25 or P50) was slurried with 1M HCl (25 ml) and cooled to 0° C., with stirring, before the addition of an equal volume of 1M ammonium persulphate in water, slowly over 5 minutes. After 1 h, the polymer particles were removed by filtration and washed with water and oven dried. The material was pressed into disks of approx 1 cm diameter using a hand press. Conductivity was measured by the two-probe method using a digital multimeter (Table 2).

TABLE 2
Conductivity of the vinyl addition polymers of
Table 1, following polyaniline formation using ammonium
persulphate in HC1 at 0° C., compared with aniline polymers
prepared in the same way at either 0° C. or at room
temperature.

| Polymer | Conductivity (S cm⁻¹) |
|---|---|
| P0-PANI | 6.18 |
| P5-PANI | 12.66 |
| P10-PANI | 7.94 |
| P25-PANI | 4.7 |
| P50-PAN1 | 0.83 |
| Polyaniline (0° C.) | 6.86 |
| Polyaniline (RT) | 3.54 |

### EXAMPLE 4

### Simultaneous Formation of Polyaniline and Vinyl Addition Polymerization of NMAEA in a One-Pot Reaction

Monomer (NMAEA) was dissolved in 1 M HCl (25 ml) and cooled in ice before the addition of an equal volume of 1 M ammonium persulphate, slowly over 5 minutes. The polymer separated as a fine precipitate. After 1 h reaction the polymer was collected by filtration and washed with water before drying in an oven. Conductivity of a pressed disk of the material was measured as described above (Table 3).

TABLE 3
Conductivity of the material obtained by
simultaneous polymerization of the aniline and vinyl
groups of NMAEA (NMAEA-ox) compared with polyaniline
prepared at 0° C. and RT.

| Polymer | Conductivity (S cm⁻¹) |
|---|---|
| P0-PANI | 6.18 |
| NMAEA-ox | 8.06 |
| Polyaniline (0° C.) | 6.86 |
| Polyaniline (RT) | 3.54 |

### EXAMPLE 5

### Electropolymerization of the Aniline Group of NMAEA

An Autolab Instrument (Netherlands) was utilized for all electrochemical experiments. A conventional three-electrode cell with a gold (evaporated 5 nm Cr and 45 nm Au film) on glass working electrode, a platinum counter-electrode and a silver/silver chloride (Ag/AgCl) reference electrode was utilized. The gold electrode was cycled (15 cycles) between −0.4 V and +1.0 V (vs. Ag/AgCl) at a scan rate of 50 mV/s in a 2.44 mM solution of NMAEA in 50 mM HClO₄. The gold electrode bearing the electropolymerized polyaniline film with pendant methacrylamide groups was washed with water and dried.

### EXAMPLE 6

### Cross-Linking of Electropolymerized Film of NMAEA

The electropolymerized film of NMAEA on a gold electrode was immersed in a solution of N,N-diethyldithiocarbamic acid benzyl ester (iniferter) in acetonitrile contained within a Petri dish (25 mm diameter). Oxygen was removed by purging with argon for 10 minutes. The Petri dish was covered with a flat glass plate and the edges sealed with Parafilm® to maintain an inert atmosphere over the solution. The film was then irradiated for 20 minutes through the solution using a Philips UV lamp mounted at 8 cm from the sample to activate the iniferter and generate benzyl radicals to react with the double bonds of the polymer and cause crosslinking. The electrode was then washed with methanol and dried in a stream of argon.

### EXAMPLE 7

### Grafting of Vinyl Polymers to Electropolymerized Film of NMAEA

The iniferter-modified electropolymerized film (Example 6) was placed in a Petri dish, immersed in a solution containing ethylene glycol dimethacrylate and methacrylic acid (8:2), dissolved in (DMF), previously degassed by purging with argon for 5 minutes. The Petri dish was covered with a glass cover plate, sealed with Parafilm® after purging with argon to maintain an inert atmosphere. The electropolymerised iniferter-modified layer was irradiated using a Philips UV lamp for 30 minutes to graft a cross-linked polymer layer on the surface of the electrode-bound conjugated polymer layer.

### EXAMPLE 8

### Formation of Conjugated Polymer Thin Films and Coatings

A clean glass microscope slide was dipped into a 1% solution of P0 (example 3) in methanol. The excess solution was allowed to drain from the slide and the coating was dried in a stream of air. The dried microscope slide, covered with a thin layer of the addition polymer with pendant aniline side chains, was treated with an ice-cold solution of HCl (0.5 M) and ammonium persulphate (0.5 M). The coated slide was left in contact with the ice-cold solution for a period of from 5 mins to 1 h, after which time the slide was rinsed with water and dried in air. The conductivity of the coating was found to be 10-11 S cm⁻¹.

### EXAMPLE 9

### Lithographic Patterning of Conjugated Polymer by a Two Stage Polymerization Process

Sections of glass microscope slide were cleaned by immersion in a mixture of water, ammonia and hydrogen peroxide (5:1:1 v:v:v) for 20 minutes, which results in activation of surface hydroxyl groups. The treated glass was washed with distilled water and dried in a stream of air. The activated glass slides were immersed in a solution of γ-methacryloyloxypropyl trimethoxysilane (2%) in toluene overnight. The silylated glass slides were then spin-coated with a solution of NMAEA and ethyleneglycol dimethacrylate (9:1)+2% azo-bis-cyclohexanecarbonitrile (free radical initiator). The cast layers were placed on a black paper surface in the base of a glass Petri dish and covered with an opaque mask, in which material had been cut away to expose tracks of 2 mm width, 2 mm apart. The air space above the masked slide was purged with argon before covering the Petri dish with a glass lid. The photosensitive glass slide and mask were placed under a high power UV lamp (Dr. Hönle) and exposed to UV radiation for 10 minutes. After exposure the mask was removed and the imaged polymer areas developed by washing the glass surface with methanol, with at least two changes of solvent. The glass with the transparent polymer tracks was transferred to a solution of HCl (1 M) in a beaker held at 0° C. before the addition of a solution of ammonium persulphate (1 M), also at 0° C. The dark bands of polyaniline at the positions imaged by the UV lithography were seen to develop, corresponding to polyaniline formation due to oxidation of the side chains of the resist material. Conductivity measurements showed, after drying, a conductivity of 11 S cm⁻¹ in the imaged areas.

### EXAMPLE 10

### Coating of Fibres with a Conjugated Polymer

A solution of P0 (example 3) was prepared in 0.01M HCl solution. A cellulose fibre membrane (filter paper, Whatman No.1) was soaked in the P0 solution. The excess polymer solution was drained from the paper and the polymer solution optionally fixed by washing with 0.1 M NaOH solution, followed by water and dried. The pre-treated paper was then immersed in an ice-cold solution of HCl (0.5 M) and ammonium persulphate (0.5 M) for up to 1 h to allow the conjugated polymer to form.

### EXAMPLE 11

### Formation of Patterned Conjugated Polymer Surface Features by Writing or Printing Methods

A methanol solution of P0 was applied to a silylated cellulose fibre membrane (Phase sep filter paper, Whatman) using a writing device, such as a pen or brush. The polymer “writing” was optionally fixed by washing with aqueous base and water before drying. The paper treated with polymer “invisible ink” was then developed by immersion into a solution of acidified ammonium persulphate, (0.5 M in both ammonium persulphate and HCl) at 0° C. or at room temperature.

### EXAMPLE 12

### Lithographic Patterning of Conjugated Polymer by a Two Stage Polymerization Process with Entirely Aqueous Processing Steps

Sections of polymer sheet were cleaned by immersion in methanol for 20 minutes. The treated polymer sheet was washed with distilled water and dried in a stream of air. The cleaned sheet was then spin-coated with a solution of NMAEA and N,N′-methylene-bis-acrylamide (9:1)+2% of water soluble initiator, azo-bis-amidinopropanehydrochoride. The cast layers were placed on a black paper surface in the base of a glass Petri dish and covered with an opaque mask, in which material had been cut away to expose tracks of 2 mm width, 2 mm apart. The air space above the masked slide was purged with argon before covering the Petri dish with a glass lid. The photosensitive glass slide and mask was placed under a high power UV lamp (Dr. Hönle) and exposed to UV radiation for 10 minutes. After exposure the mask was removed and the imaged polymer areas developed by washing the glass surface with water, with at least two changes of solvent. The glass with the transparent polymer tracks was transferred to a solution of HCl (1 M) in a beaker held at 0° C. before the addition of a solution of ammonium persulphate (1 M), also at 0° C. Dark bands of polyaniline at the positions imaged by the UV lithography were seen to develop, corresponding to polyaniline formation due to oxidation of the side chains of the resist material. Conductivity measurements showed, after drying, a conductivity of 10 S cm⁻¹ in the imaged areas.

1. A method of preparing a polymer comprising:
(a) providing a monomer of the form M-S where M is a moiety capable of polymerisation to form a conjugated polymer chain, and S is a moiety including a double bond whereby it is capable of addition polymerisation;
(b) causing polymerisation of the M-moieties, optionally together with a comonomer, to form a conjugated polymer chain;
(c) causing polymerisation of the S-moieties, optionally together with a comonomer;
wherein steps (b) and (c) are carried out in either order or simultaneously.

2. A method according to claim 1, wherein the M-moiety is an optionally substituted aniline, pyrrole or thiophene residue.

3. A method according to claim 2, wherein the M-moiety is an optionally substituted aniline group, and the S-moiety is connected to the aniline nitrogen atom.

4. A method according to claim 2, wherein the M-moiety is an aniline group which is unsubstituted at the 4-position.

5. A method according to claim 1, wherein the conjugated polymer chain is a polyaniline, polypyrrole or polythiophene chain.

6. A method according to claim 5, wherein the M-moiety is an optionally substituted aniline, pyrrole or thiophene residue.

7. A method according to claim 5, wherein the conjugated polymer chain is a polyaniline.

8. A method according to claim 1, wherein the S-moiety comprises an acrylate ester group, a methacrylate ester group, an acrylamido group or a methacrylamido group.

9. A method according to claim 1, wherein the monomer is selected from N-(methacrylamidoethyl)-aniline, N-(acrylamidoethyl)-aniline, N-(methacryloyloxyethyl)-aniline and N-(acryloyloxyethyl)-aniline.

10. A method according to claim 1, wherein step (b) is carried out using chemical oxidation or electropolymerisation.

11. A method according to claim 1, wherein step (c) is carried out using free radical polymerisation.

12. A method according to claim 1, wherein step (b) is carried out before step (c), to produce a composition comprising a first polymer containing a conjugated polymer chain and including polymerisable S-moieties.

13. A method according to claim 12, wherein a composition containing said first polymer is used to coat a surface, whereafter step (c) is carried out to produce a polymer coating on the surface.

14. A method according to claim 12, wherein said first polymer and a photochemically or thermally activated iniferter are reacted together with irradiation or heating to cause attachment of the iniferter to double bonds of the S-moieties to produce a second polymer; and the second polymer is immersed in a solution containing additional monomer(s) which are grafted to the second polymer.

15. A method according to claim 14, wherein said grafting is carried out in the presence of a template substance which is subsequently removed to leave cavities, whereby the end product is a molecularly imprinted polymer.

16. A method according to claim 1, wherein step (c) is carried out before step (b).

17. A method according to claim 16 in which a film or layer comprising the monomer M-S is formed on a surface and said polymerisation step (c) is carried out to form a polymer coating on the surface.

18. A method according to claim 17 in which said film or layer is partially covered by a mask, exposed portions are irradiated to effect polymerisation, and thereafter the non-exposed and non-irradiated portions are selectively removed.

19. A method according to claim 16 in which the polymer resulting from step (c) is applied to an article to form a surface coating.

20. A method according to claim 16 in which the polymer resulting from step (c) is formed into fibres.

21. A method according to claim 16, including a subsequent polymerisation step (b) effected by treating the step (c) polymer with a solution capable of initiating step (b) polymerisation.

22. A polymer derivable from monomers comprising monomers of the form M-S where M is a moiety capable of polymerisation to form a conjugated polymer chain, and S is a moiety including a double bond whereby it is capable of addition polymerisation; said polymer having conjugated polymer chains as derived from polymerisation of said M moieties, optionally together with a comonomer; said conjugated polymer chains being cross-linked by linkages as derived from polymerisation of said S moieties, optionally together with a comonomer.

23. A polymer derivable from monomers comprising monomers of the form M-S where M is a moiety capable of polymerisation to form a conjugated polymer chain, and S is a moiety including a double bond whereby it is capable of addition polymerisation; said polymer having conjugated polymer chains as derived from polymerisation of said M moieties, optionally together with a comonomer; said conjugated polymer chains being cross-linked by linkages as derived from polymerisation of said S moieties, optionally together with a comonomer, as produced by the method of claim 1.

24. A monomer of the form M-S suitable for use in the method of claim 1 selected from N-(methacrylamidoethyl)-aniline, N-(acrylamidoethyl)-aniline, N-(methacryloyloxyethyl)-aniline and N-(acryloyloxyethyl)-aniline.

25. The polymer of claim 22, wherein the monomer of the form is M-S is N-(methacrylamidoethyl)-aniline.

26. A method according to claim 8 wherein the spacer is connected to the M moiety by a spacer group 2-6 atoms n length.

27. A method according to claim 20 including a further step of using said fibers to produce articles comprising said fibres.
